(19) United States
(12) Patent Application Publication
(10) Pub. No.: US 2008/0277703 A1
(43) Pub. Date: Nov. 13, 2008

(54) MAGNETORESISTIVE RANDOM ACCESS MEMORY AND METHOD OF MANUFACTURING THE SAME

(76) Inventor: Masayoshi Iwayama, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/107,955

(22) Filed: Apr. 23, 2008

(30) Foreign Application Priority Data
Apr. 27, 2007 (JP) 2007-119332

(51) Int. Cl. H01L 31/062; G11C 11/00; H01L 21/00

(52) U.S. Cl. 257/295; 365/158; 438/3; 257/E21.665; 257/E27.104

(57) ABSTRACT

A magnetic random access memory includes a single tunnel junction element which includes a first fixed layer, a first recording layer, and a first nonmagnetic layer, a double tunnel junction element which includes a second fixed layer and a third fixed layer, a second recording layer, a second nonmagnetic layer formed between the second fixed layer and the second recording layer, and a third nonmagnetic layer formed between the third fixed layer and the second recording layer, and in which the magnetization directions in the second fixed layer and the second recording layer take one of the parallel state and the antiparallel state in accordance with a direction of an electric current flowing between the second fixed layer and the second recording layer, and a transistor connected to a memory cell having the single tunnel junction element and the double tunnel junction element connected in parallel.

### CROSS-REFERENCE TO RELATED APPLICATIONS

This application is based upon and claims the benefit of priority from prior Japanese Patent Application No. 2007-119332, filed Apr. 27, 2007, the entire contents of which are incorporated herein by reference.

### BACKGROUND OF THE INVENTION

1. Field of the Invention

The present invention relates to a spin injection type magnetoresistive random access memory and a method of manufacturing the same.

2. Description of the Related Art

A conventional spin injection type magnetoresistive random access memory (MRAM) comprises only one magnetic tunnel junction element for one selection transistor. This makes it difficult to increase the capacity.

Note that pieces of prior art reference information related to the present invention are as follows.

[Patent reference 1] Jpn. Pat. Appln. KOKAI Publication No. 2005-340468

[Patent reference 1] Jpn. Pat. Appln. KOKAI Publication No. 2000-208831

### BRIEF SUMMARY OF THE INVENTION

A magnetic random access memory according to the first aspect of the present invention comprising a single tunnel junction element which includes a first fixed layer having a fixed magnetization direction, a first recording layer having a reversible magnetization direction, and a first nonmagnetic layer formed between the first fixed layer and the first recording layer, and in which the magnetization directions in the first fixed layer and the first recording layer take one of a parallel state and an antiparallel state in accordance with a direction of an electric current flowing between the first fixed layer and the first recording layer; a double tunnel junction element which includes a second fixed layer and a third fixed layer each having a fixed magnetization direction, a second recording layer having a reversible magnetization direction, a second nonmagnetic layer formed between the second fixed layer and the second recording layer, and a third nonmagnetic layer formed between the third fixed layer and the second recording layer, and in which the magnetization directions in the second fixed layer and the second recording layer take one of the parallel state and the antiparallel state in accordance with a direction of an electric current flowing between the second fixed layer and the second recording layer; and a transistor connected to a memory cell having the single tunnel junction element and the double tunnel junction element connected in parallel.

A magnetic random access memory manufacturing method according to the second aspect of the present invention comprising forming a transistor; forming a lower electrode connecting to the transistor; forming, on the lower electrode, a first stacked portion in which a first fixed layer, a first nonmagnetic layer, a first recording layer, a second nonmagnetic layer, a second fixed layer, and a first upper electrode are sequentially stacked, and a second stacked portion in which a third fixed layer, a third nonmagnetic layer, a second recording layer, a fourth nonmagnetic layer, a fourth fixed layer, and a second upper electrode are sequentially stacked; forming an interlayer dielectric film covering the first stacked portion and the second stacked portion; exposing only the first upper electrode by partially removing the interlayer dielectric film; forming a trench by removing the first upper electrode and the second fixed layer; forming a third upper electrode in the trench; and forming a bit line on the first upper electrode and the third upper electrode, wherein the first fixed layer, the first nonmagnetic layer, and the first recording layer form a single tunnel junction element, the third fixed layer, the third nonmagnetic layer, the second recording layer, the fourth nonmagnetic layer, and the fourth fixed layer form a double tunnel junction element, and the transistor is connected to a memory cell having the single tunnel junction element and the second single tunnel junction element connected in parallel by the lower electrode and the bit line.

### BRIEF DESCRIPTION OF THE SEVERAL VIEWS OF THE DRAWING

FIG. 1 is a plan view showing a magnetoresistive random access memory according to an embodiment of the present invention;

FIG. 2 is a sectional view taken along a line II-II in FIG. 1;

FIG. 3 is a sectional view showing a manufacturing step of the magnetoresistive random access memory according to the embodiment of the present invention;

FIG. 4A is a plan view showing a fabrication step, which follows FIG. 3, of the magnetoresistive random access memory according to the embodiment of the present invention;

FIG. 4B is a sectional view taken along a line IVB-IVB in FIG. 4A;

FIG. 5 is a sectional view showing a manufacturing step, which follows FIGS. 4A and 4B, of the magnetoresistive random access memory according to the embodiment of the present invention;

FIG. 6 is a sectional view showing a manufacturing step, which follows FIG. 5, of the magnetoresistive random access memory according to the embodiment of the present invention;

FIG. 7 is a sectional view showing a manufacturing step, which follows FIG. 6, of the magnetoresistive random access memory according to the embodiment of the present invention;

FIG. 8 is a sectional view showing a manufacturing step, which follows FIG. 7, of the magnetoresistive random access memory according to the embodiment of the present invention;

FIG. 9A is a plan view showing a manufacturing step of a stacked portion of an MTJ element according to the embodiment of the present invention;

FIG. 9B is a sectional view taken along a line IXB-IXB in FIG. 9A;

FIG. 10 is a sectional view showing a manufacturing step, which follows FIGS. 9A and 9B, of the MTJ element according to the embodiment of the present invention;

FIG. 11 is a sectional view showing a manufacturing step, which follows FIG. 10, of the stacked portion of the MTJ element according to the embodiment of the present invention;

FIG. 12A is a sectional view showing a manufacturing step, which follows FIG. 11, of the stacked portion of the MTJ element according to the embodiment of the present invention;

FIG. 12B is a sectional view taken along a line XIIB-XIIB in FIG. 12A;

FIG. 12C is a sectional view taken along a line XIIC-XIIC in FIG. 12A;

FIG. 13A is a plan view showing a manufacturing step, which follows FIGS. 12A to 12C, of the stacked portion of the MTJ element according to the embodiment of the present invention;

FIG. 13B is a sectional view taken along a line XIIIB-XIIIB in FIG. 13A;

FIG. 13C is a sectional view taken along a line XIIIC-XIIIC in FIG. 13A;

FIG. 14A is a partially enlarged view of FIG. 13A;

FIG. 14B is a sectional view taken along a line XIVB-XIVB in FIG. 14A;

FIG. 14C is a sectional view taken along a line XIVC-XIVC in FIG. 14A;

FIG. 14D is a sectional view taken along a line XIVD-XIVD in FIG. 14A;

FIG. 14E is a sectional view taken along a line XIVE-XIVE in FIG. 14A;

FIG. 15A is a plan view showing a manufacturing step, which follows FIGS. 13A to 13C, of the stacked portion of the MTJ element according to the embodiment of the present invention;

FIG. 15B is a sectional view taken along a line XVB-XVB in FIG. 15A;

FIG. 16A is a plan view showing a manufacturing step, which follows FIGS. 15A and 15B, of the stacked portion of the MTJ element according to the embodiment of the present invention;

FIG. 16B is a sectional view taken along a line XVIB-XVIB in FIG. 16A;

FIG. 17 is a view for explaining the resistance values in a low-resistance state and high-resistance state of a single tunnel junction element and double tunnel junction element of a quaternary memory according to the embodiment of the present invention;

FIG. 18 is a view for explaining quaternary data of a memory cell according to the embodiment of the present invention;

FIG. 19 is a graph showing changes in resistance, when a voltage is applied, of the quaternary memory according to the embodiment of the present invention;

FIG. 20 is a view for explaining the resistance values in the low-resistance state and high-resistance state of a single tunnel junction element and double tunnel junction element of a ternary memory according to the embodiment of the present invention;

FIG. 21 is a view for explaining ternary data of a memory cell according to the embodiment of the present invention;

FIG. 22 is a graph showing changes in resistance, when a voltage is applied, of the ternary memory according to the embodiment of the present invention;

FIGS. 23A to 23C are sectional views showing examples of tunnel junction layers of the single tunnel junction element and double tunnel junction element according to the embodiment of the present invention; and

FIG. 24 is a sectional view showing an example in which the sizes of the single tunnel junction element and double tunnel junction element according to the embodiment of the present invention are different.

### DETAILED DESCRIPTION OF THE INVENTION

Embodiments of the present invention will be explained below with reference to the accompanying drawing. In the following explanation, the same reference numerals denote the same parts throughout the drawing.

### [1] Layout and Structure of Memory Cells

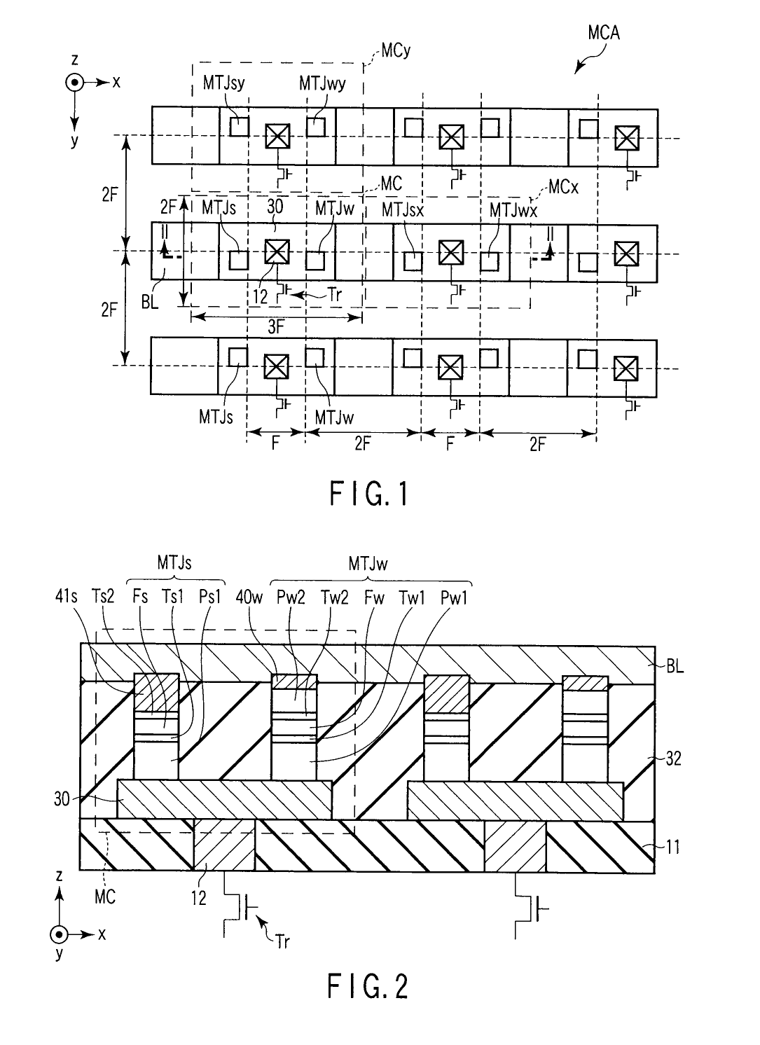

FIG. 1 is a plan view of a memory cell array of a magnetoresistive random access memory according to an embodiment of the present invention. FIG. 2 is a sectional view taken along a line II-II in FIG. 1. The layout and structure of memory cells will be explained below.

As shown in FIG. 1, a memory cell MC has a 2-bit MTJ (Magnetic Tunnel Junction) element (magnetoresistive effect element) including a single tunnel junction element MTJs and double tunnel junction element MTJw. A transistor Tr is connected to the 2-bit memory cell MC.

In the memory cell MC, the single tunnel junction element MTJs and double tunnel junction element MTJw are arranged straight in a direction (the x direction) in which bit lines BL run. A memory cell array MCA is formed by arranging memory cells MC each having this configuration in the x and y directions.

Referring to FIG. 1, the single tunnel junction elements MTJs and double tunnel junction elements MTJw are alternately arranged straight in the x direction. In the y direction, however, columns including only the single tunnel junction elements MTJs and columns including only the double tunnel junction elements MTJw exist.

Note that the arrangement can be changed as follows as long as each cell includes the single tunnel junction element MTJs and double tunnel junction element MTJw. For example, it is possible to continuously arrange the single tunnel junction elements MTJs or double tunnel junction elements MTJw straight in the x direction, or mix the single tunnel junction elements MTJs and double tunnel junction elements MTJw in the same column in the y direction.

In this embodiment, letting F be the feature size, the width of the memory cell MC in the direction (x direction) in which the bit lines BL run is 3F, and the width of the memory cell MC in a direction (the y direction) perpendicular to the direction in which the bit lines BL run is 2F. Accordingly, the memory cell MC has a 2-bit MTJ element (the single tunnel junction element MTJs and double tunnel junction element MTJw) in a cell area of 6F².

In the memory cell MC, the distance between the single tunnel junction element MTJs and double tunnel junction element MTJw, i.e., the distance from that side surface of the single tunnel junction element MTJs which faces the double tunnel junction element MTJw to that side surface of the double tunnel junction element MTJw which faces the single tunnel junction element MTJs is F.

In the memory cell MC and a memory cell MCx adjacent to each other in the x direction, the distance between the double tunnel junction element MTJw of the memory cell MC and a single tunnel junction element MTJsx of the memory cell MCx, i.e., the distance from that side surface of the double tunnel junction element MTJw which faces the single tunnel junction element MTJs to that side surface of the single tunnel junction element MTJsx which faces a double tunnel junction element MTJwx is 2F.

In the memory cell MC and a memory cell MCy adjacent to each other in the y direction, the distance from the single tunnel junction element MTJs and double tunnel junction element MTJw of the memory cell MC to a single tunnel junction element MTJsy and double tunnel junction element MTJwy of the memory cell MCy, i.e., the distance from those side surfaces of the single tunnel junction element MTJs and double tunnel junction element MTJw which face the memory cell MCy to those side surfaces of the single tunnel junction element MTJsy and double tunnel junction element MTJwy which face the memory cell MC is 2F.

As shown in FIG. 2, the single tunnel junction element MTJs and double tunnel junction element MTJw are formed on the same lower electrode 30. Upper electrodes 41s and 40w are respectively formed on the single tunnel junction element MTJs and double tunnel junction element MTJw. The bit line BL is formed on the upper electrodes 41s and 40w. Accordingly, the upper end portions of the single tunnel junction element MTJs and double tunnel junction element MTJw are connected to the bit line BL, and the lower end portions of the single tunnel junction element MTJs and double tunnel junction element MTJw are connected to the lower electrode 30. As a consequence, the single tunnel junction element MTJs and double tunnel junction element MTJw are connected in parallel.

The single tunnel junction element MTJs has a fixed layer (pinned layer) Ps1 in which the magnetization direction is fixed, a recording layer (free layer) Fs in which the magnetization direction is reversible, and a tunnel junction layer (nonmagnetic layer) Ts1 formed between the fixed layer Ps1 and recording layer Fs. That is, in the single tunnel junction element MTJs, ferromagnetic layers (the fixed layer Ps1 and recording layer Fs) sandwich the tunnel junction layer Ts1. A tunnel junction layer Ts2 is formed on the recording layer Fs of the single tunnel junction element MTJs, and the upper electrode 41s is formed on the tunnel junction layer Ts2. The fixed layer Ps1, tunnel junction layer Ts1, recording layer Fs, tunnel junction layer Ts2, and upper electrode 41s forming a stacked portion have the same planar shape, and their side surfaces are aligned. Note that in this embodiment, all the single tunnel junction elements MTJs in the memory cell array MCA have identical stacked structures.

The double tunnel junction element MTJw has fixed layers Pw1 and Pw2 in which the magnetization direction is fixed, a recording layer Fw in which the magnetization direction is reversible, a tunnel junction layer Tw1 formed between the fixed layer Pw1 and recording layer Fw, and a tunnel junction layer Tw2 formed between the fixed layer Pw2 and recording layer Fw. That is, in the double tunnel junction element MTJw, ferromagnetic layers (the fixed layer Pw1 and Pw2 and recording layer Fw) sandwich the two tunnel junction layers Tw1 and Tw2. The upper electrode 40w is formed on the fixed layer Pw2 of the double tunnel junction element MTJw. The fixed layer Pw1, tunnel junction layer Tw1, recording layer Fw, tunnel junction layer Tw2, fixed layer Pw2, and upper electrode 40w forming a stacked portion have the same planar shape, and their side surfaces are aligned. Note that in this embodiment, all the double tunnel junction elements MTJw in the memory cell array MCA have identical stacked structures.

The stacked portions of the single tunnel junction element MTJs and double tunnel junction element MTJw have, e.g., the following relationships. The film thicknesses of the fixed layer Ps1 and Pw1 are the same, and the upper surfaces of the fixed layers Ps1 and Pw1 have the same height. The film thicknesses of the tunnel junction layers Ts1 and Tw1 are the same, and the upper surfaces of the tunnel junction layers Ts1 and Tw1 have the same height. The film thicknesses of the recording layers Fs and Fw are the same, and the upper surfaces of the recording layers Fs and Fw have the same height. The film thicknesses of the tunnel junction layers Ts2 and Tw2 are the same, and the upper surfaces of the tunnel junction layers Ts2 and Tw2 have the same height. The film thickness of the upper electrode 41s is the same as the total film thickness of the fixed layer Pw2 and upper electrode 40w, and the upper surfaces of the upper electrodes 41s and 40w have the same height.

Note that it is also possible to remove the tunnel junction layer Ts2 of the single tunnel junction element MTJs, and increase the film thickness of the upper electrode 41s by an amount corresponding to the film thickness of the tunnel junction layer Ts2, thereby setting the upper surfaces of the upper electrodes 41s and 40w at the same height.

### [2] Memory Cell Manufacturing Method

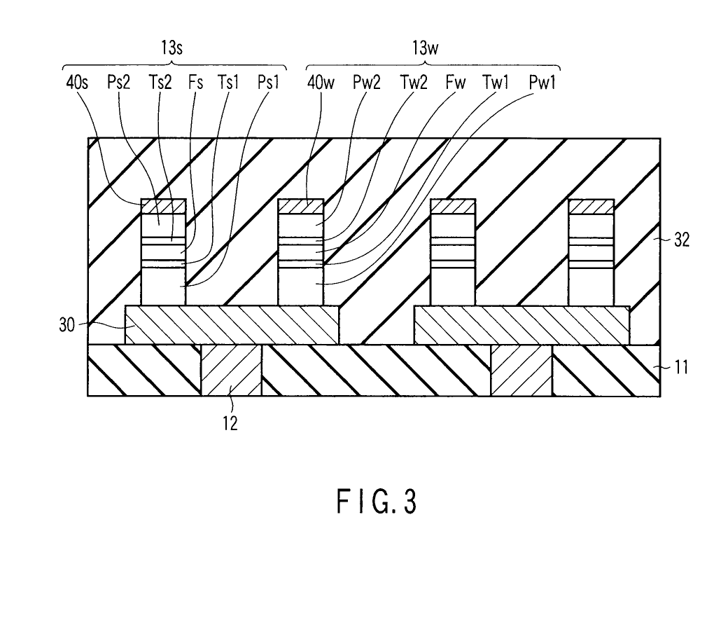

FIGS. 3 to 8 are views showing manufacturing steps of the memory cell of the magnetoresistive random access memory according to the embodiment of the present invention. A method of manufacturing the memory cell of the magnetoresistive random access memory will be explained below.

First, as shown in FIG. 3, stacked portions 13s and 13w are formed on a lower electrode 30 by [3] Method of Manufacturing Stacked Portions of MTJ element (to be described later). The stacked portion 13s includes a fixed layer Ps1/tunnel junction layer Ts1/recording layer Fs/tunnel junction layer Ts2/fixed layer Ps2/upper electrode 40s. The stacked portion 13w includes a fixed layer Pw1/tunnel junction layer Tw1/recording layer Fw/tunnel junction layer Tw2/fixed layer Pw2/upper electrode 40w. Then, the lower electrode 30 is separated into cells by etching such as RIE (Reactive Ion Etching). As a consequence, one lower electrode 30 is formed for the two stacked portions 13s and 13w. Subsequently, an interlayer dielectric film 32 made of a silicon oxide film or the like is deposited to cover the stacked portions 13s and 13w. The interlayer dielectric film 32 is planarized by CMP (Chemical Mechanical Polish). This planarization is performed so as not to expose the stacked portions 13s and 13w.

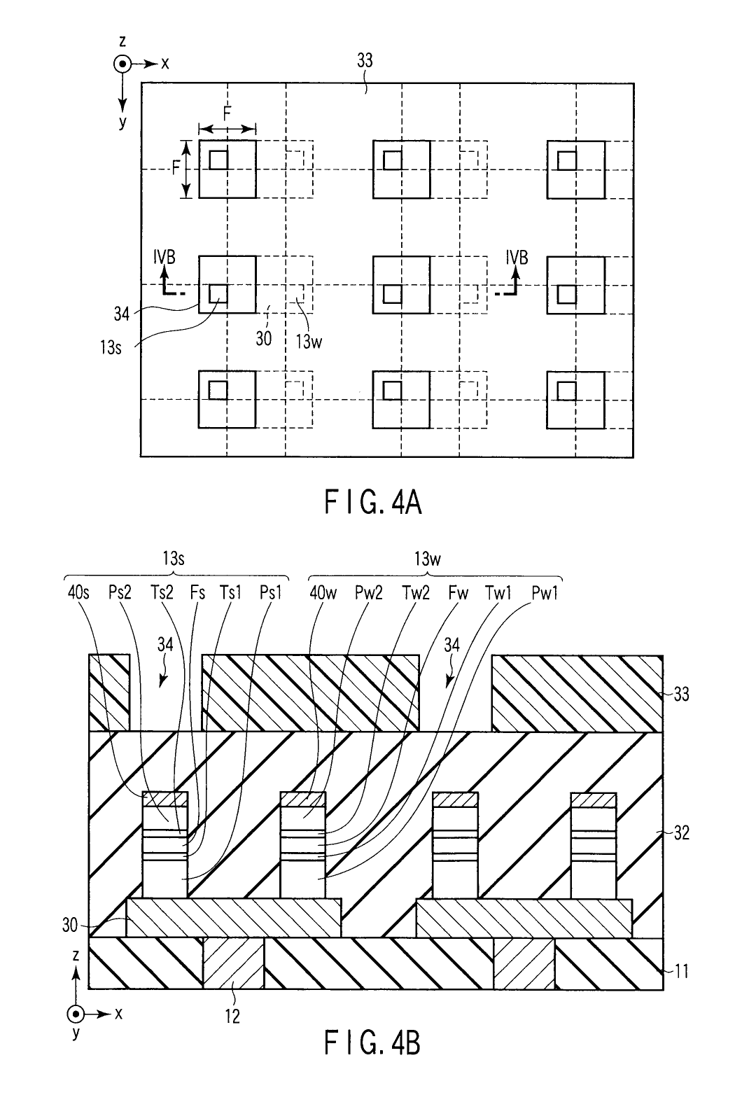

As shown in FIGS. 4A and 4B, the interlayer dielectric film 32 is coated with a resist 33. After that, the resist 33 is processed to form a hole above the stacked portion 13s of the two stacked portions 13s and 13w formed on the lower electrode 30. The size of a hole 34 in the resist 33 is, e.g., F×F.

As shown in FIG. 5, the resist 33 is used as a mask to etch the interlayer dielectric film 32 exposed in the hole 34, thereby exposing only the upper electrode 40s of the stacked portion 13s. After that, the resist 33 is removed.

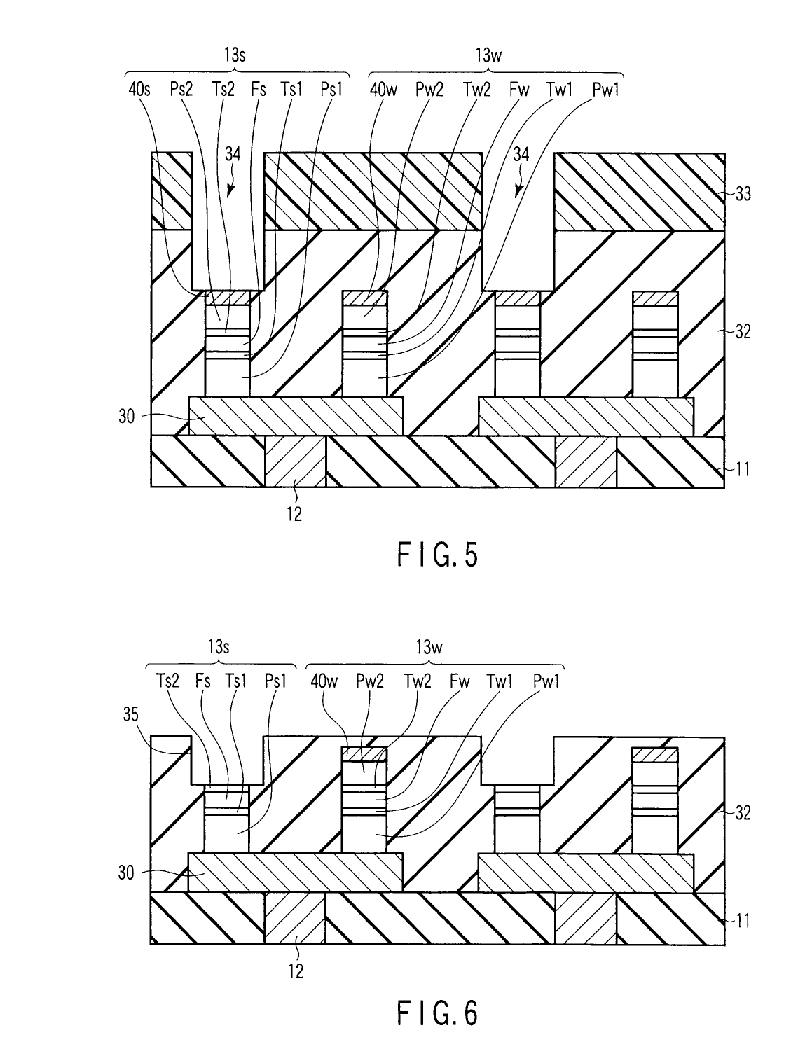

As shown in FIG. 6, the fixed layer Ps2 and upper electrode 40s of the stacked portion 13s are etched by ion milling or the like, thereby exposing the tunnel junction layer Ts2. Consequently, a trench 35 is formed.

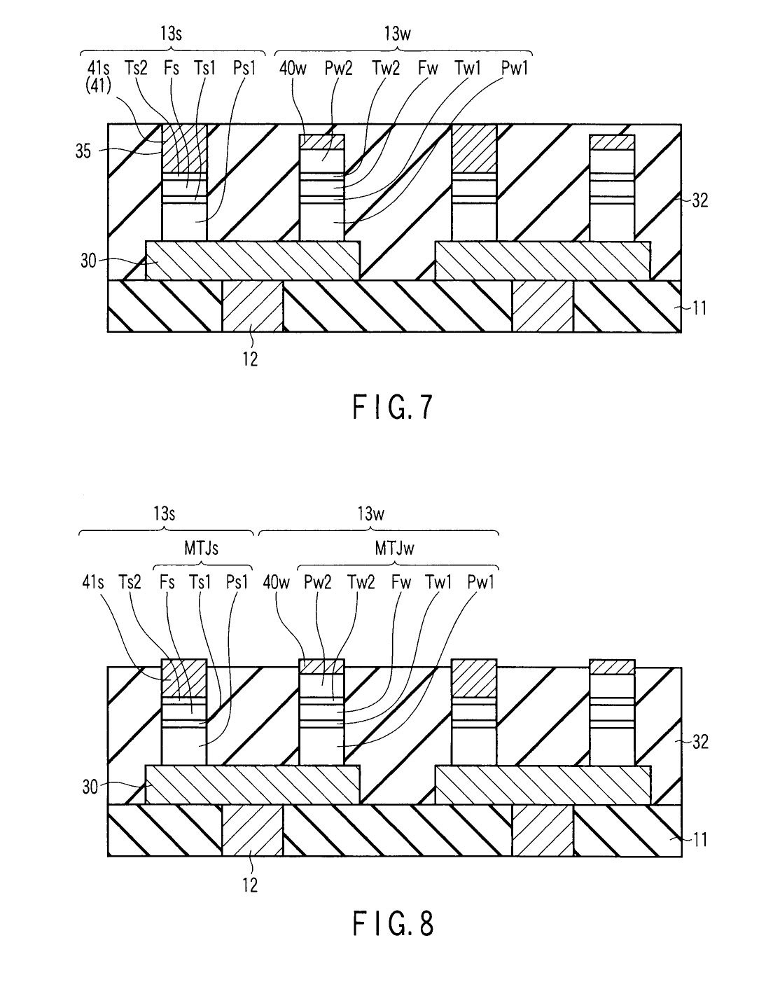

As shown in FIG. 7, an electrode material 41 such as Ta is deposited on the interlayer dielectric film 32 and buried in the trench 35 by sputtering or the like. After that, the electrode material 41 is planarized by CMP or the like, thereby exposing the interlayer dielectric film 32. In this way, an upper electrode 41s of the stacked portion 13s is formed.

As shown in FIG. 8, the interlayer dielectric film 32 and upper electrode 41s are etched back by, e.g., RIE, thereby exposing the upper electrodes 41s and 40w of the two stacked portions 13s and 13w. Consequently, the fixed layer Ps1/tunnel junction layer Ts1/recording layer Fs of the stacked portion 13s form a single tunnel junction element MTJs, and the fixed layer Pw1/tunnel junction layer Tw1/recording layer Fw/tunnel junction layer Tw2/fixed layer Pw2 of the stacked portion 13w form a double tunnel junction element MTJw.

Next, as shown in FIGS. 1 and 2, an interconnection material such as A1 is deposited on the upper electrodes 41s and 40w and interlayer dielectric film 32 by, e.g., sputtering, and processed by lithography and RIE, thereby forming bit lines BL. In this manner, the single tunnel junction element MTJs and double tunnel junction element MTJw connected in parallel are formed in the memory cell MC.

### [3] Method of Manufacturing Stacked Portions of MTJ Element

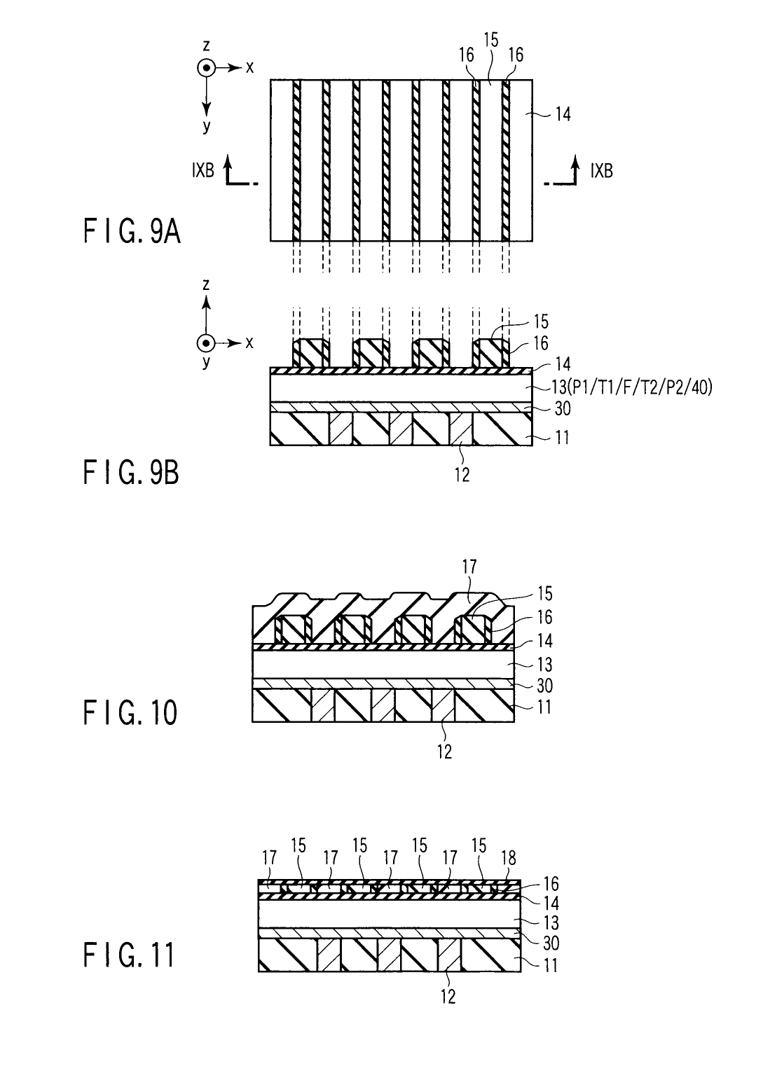

FIGS. 9A to 16B are views showing manufacturing steps of the stacked portion of the MTJ element according to the embodiment of the present invention. A method of manufacturing the stacked portion of the MTJ element will be explained below.

First, as shown in FIGS. 9A and 9B, selection transistors (not shown) are formed, and contacts 12 connecting to the selection transistors are formed in an insulating film 11. Then, a lower electrode 30 made of Ta is formed on the insulating film 11 and contacts 12, and a stacked film 13 is formed on the lower electrode 30. The stacked film 13 includes a fixed layer P1/tunnel junction layer T1/recording layer F/tunnel junction layer T2/fixed layer P2/upper electrode 40. For example, each of the fixed layers P1 and P2 is a stacked film formed by sequentially stacking PtMn, CoFe, Ru, and CoFeB, the tunnel junction layer T1 is made of MgO, the recording layer F is made of CoFeB, the tunnel junction layer T2 is made of Cu, and the upper electrode 40 is made of Ta. Subsequently, a silicon nitride film 14 as an etching stopper for a silicon oxide film 15 is deposited on the stacked film 13, and a silicon oxide film 15 is deposited on the silicon nitride film 14. Lines and spaces of the silicon oxide film 15 are then formed by photolithography and RIE. A silicon nitride film 16 is deposited on the line-and-space silicon oxide film 15 and silicon nitride film 14. The silicon oxide film 16 is then partially removed by highly perpendicular anisotropic etching (e.g., RIE). This process leaves the silicon nitride film 16 behind on only the sidewalls of the silicon oxide film 15.

As shown in FIG. 10, a silicon oxide film 17 is deposited with a high gap filling capability on the silicon nitride films 14 and 16 and silicon oxide film 15.

As shown in FIG. 11, non-masking etch back is performed on the structure shown in FIG. 10 by CMP or RIE. This process removes the round shoulders of the silicon nitride film 16 deposited on the silicon oxide film 15, and forms lines of the flat silicon oxide films 15 and 17 and silicon nitride film 16. After that, a silicon nitride film 18 as a stopper is deposited on the silicon oxide films 15 and 17 and silicon nitride film 16.

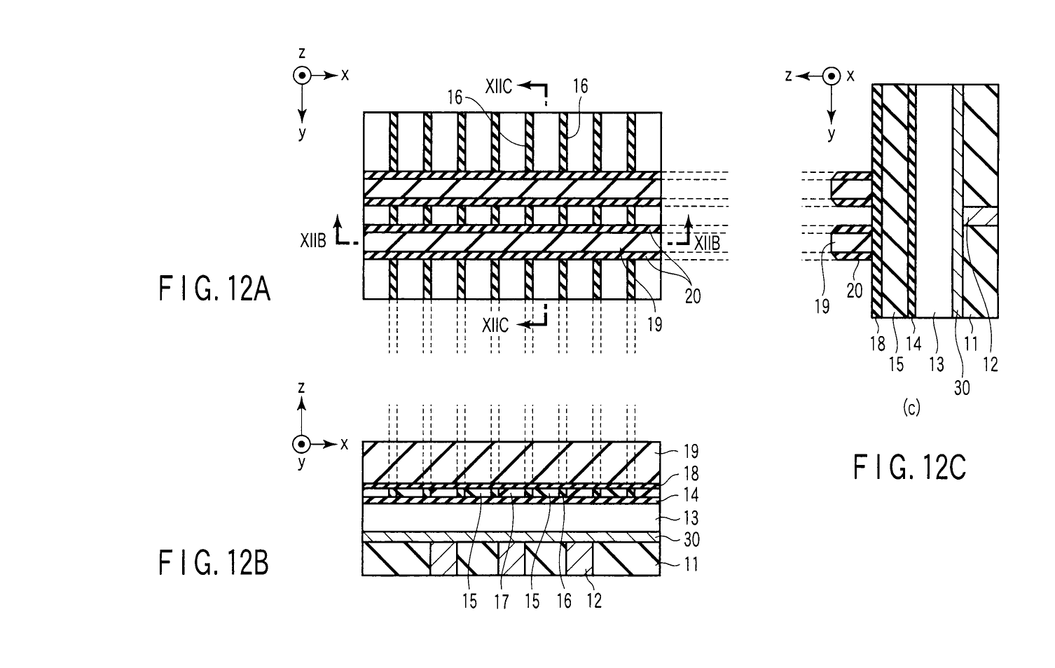

As shown in FIGS. 12A to 12C, a silicon oxide film 19 is deposited on the silicon nitride film 18. Lines and spaces of the silicon nitride film 19 are then formed by photolithography and RIE. The lines and spaces shown in FIG. 12A run in the direction (x direction) obtained by rotating the lines and spaces shown in FIG. 9A through 90°. A silicon nitride film 20 is formed on the line-and-space silicon oxide film 19 and silicon nitride film 18. The silicon nitride film 20 is then partially removed by highly perpendicular anisotropic etching (e.g., RIE). This process leaves the silicon nitride film 20 behind on only the sidewalls of the silicon oxide film 19.

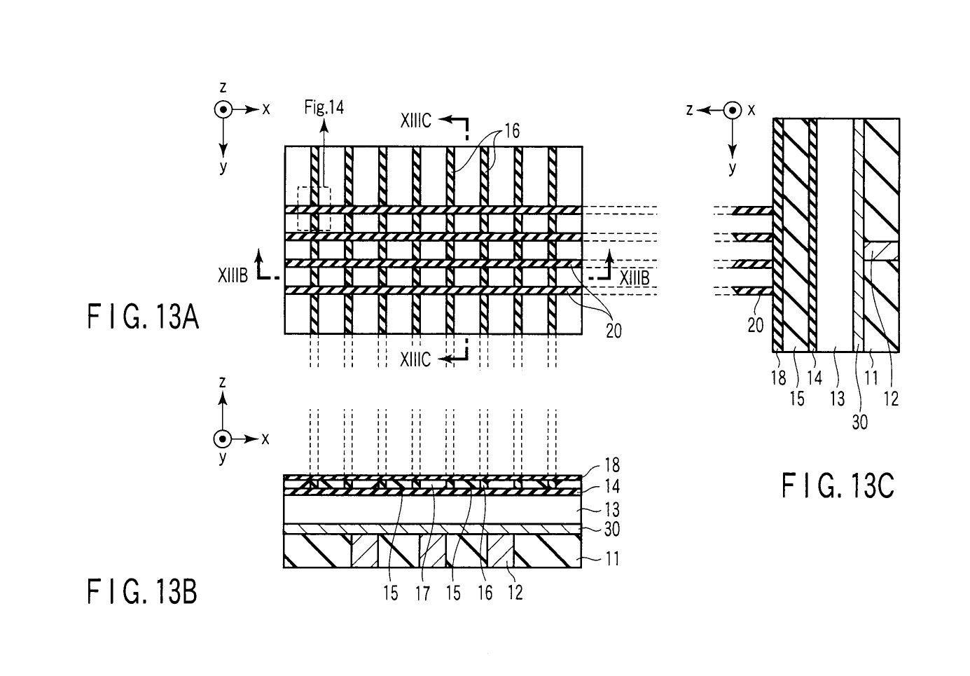

As shown in FIGS. 13A to 13C, the silicon oxide film 19 is removed by RIE or a liquid chemical.

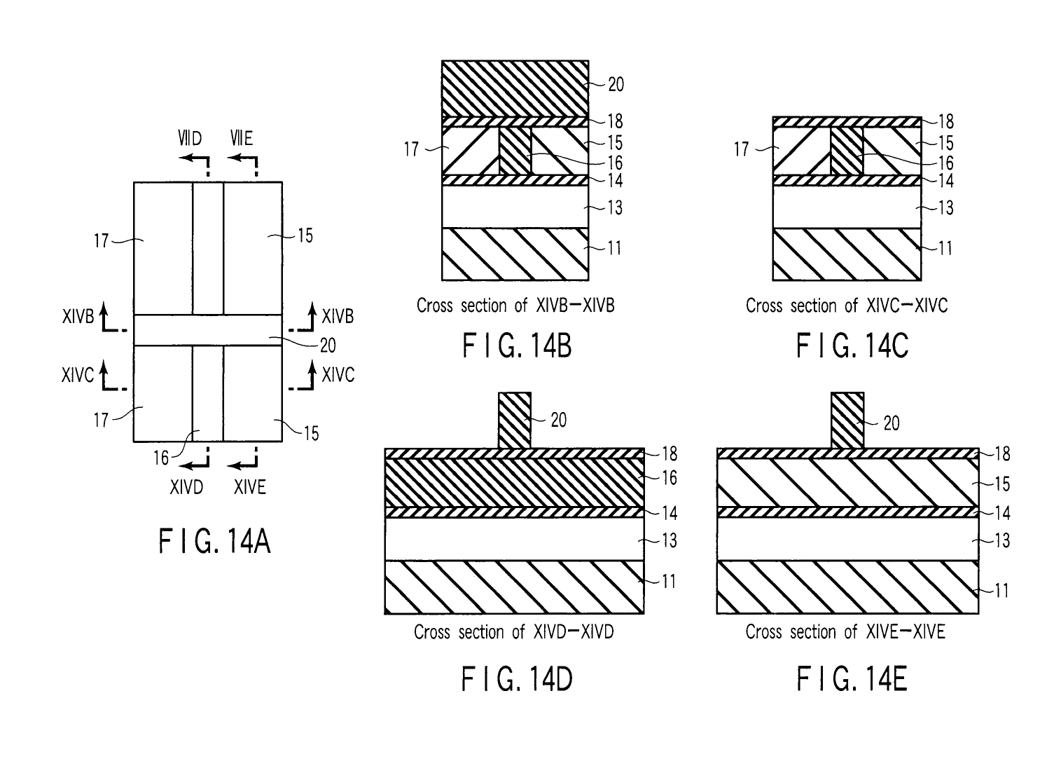

In this state, as shown in FIG. 14B, the silicon nitride film 14/silicon nitride film 16/silicon nitride film 18/silicon nitride film 20 are deposited on the stacked film 13 in a section taken along a line XIVB-XIVB in FIG. 14A.

As shown in FIG. 14C, the silicon nitride film 14/silicon nitride film 16/silicon nitride film 18 are deposited on the stacked film 13 in a section taken along a line XIVC-XIVC in FIG. 14A.

As shown in FIG. 14D, the silicon nitride film 14/silicon nitride film 16/silicon nitride film 18/silicon nitride film 20 are deposited on the stacked film 13 in a section taken along a line XIVD-XIVD in FIG. 14A.

As shown in FIG. 14E, the silicon nitride film 14/silicon oxide film 15/silicon nitride film 18/silicon nitride film 20 are deposited on the stacked film 13 in a section taken along a line XIVE-XIVE in FIG. 14A.

In a region where the silicon nitride films 16 and 20 intersect each other, therefore, only the silicon nitride films 14, 16, 18, and 20 are deposited on the staked film 13.

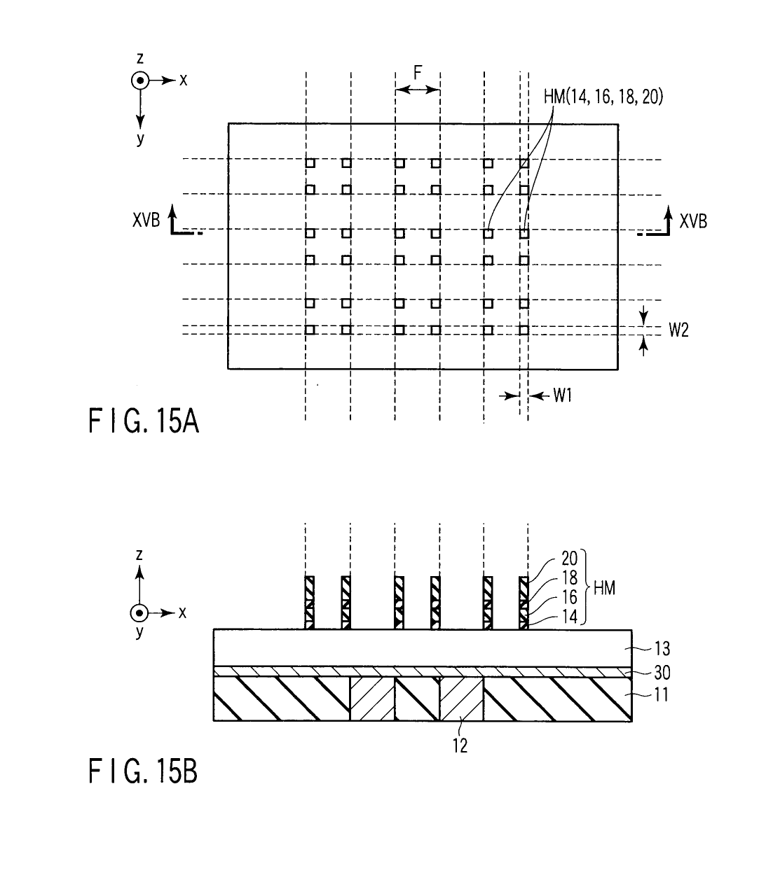

Then, as shown in FIGS. 15A and 15B, RIE is performed such that a silicon oxide film is etched faster than a silicon nitride film. Consequently, a hard mask HM including only the silicon nitride films 14, 16, 18, and 20 is formed on the stacked film 13.

In this case, the silicon nitride films 16 and 20 determine the dimensions of the hard mask HM including the silicon nitride films 14, 16, 18, and 20. A width W1 of the hard mask HM in the x direction can be controlled by the deposited film thickness of the silicon nitride film 16. A width W2 of the hard mask HM in the y direction can be controlled by the deposited film thickness of the silicon nitride film 20. This makes it possible to freely design the dimensions of the hard mask HM including the silicon nitride films 14, 16, 18, and 20, independently of the resolution of an exposure apparatus.

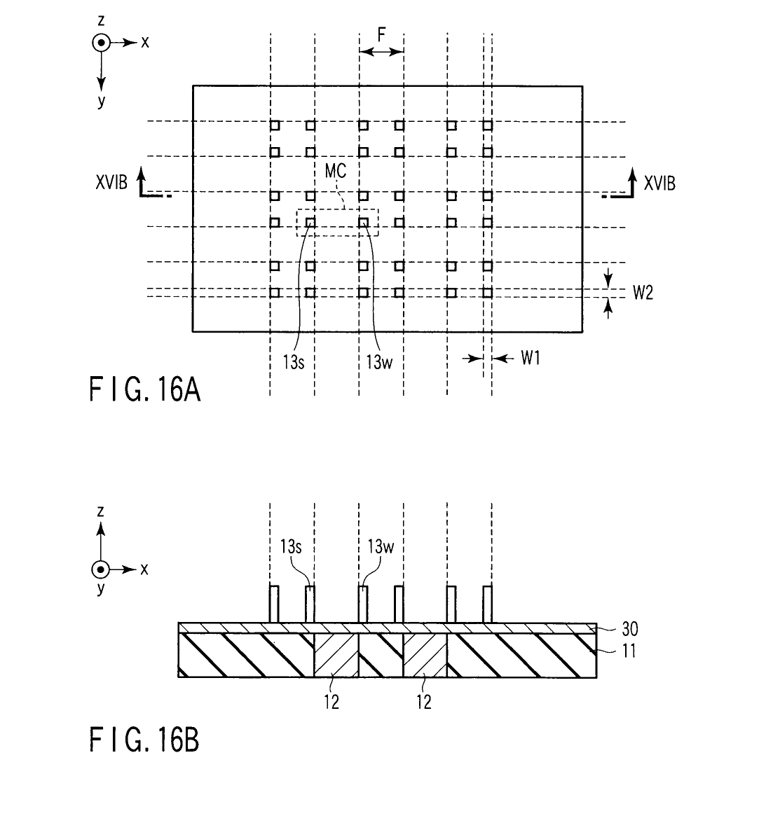

Subsequently, as shown in FIGS. 16A and 16B, the stacked film 13 is etched by ion milling or RIE by using the hard mask HM. In this way, two stacked portions 13s and 13w are formed in the memory cell MC.

Note that this embodiment selects a silicon nitride film as the material of the hard mask HM, and uses a silicon oxide film that is a material by which a high selectivity to a silicon nitride film can be obtained. However, the materials are not limited to this combination, and it is also possible to select materials having a high selectivity. Examples of the first material denoted by reference numerals 14, 16, 18, and 20 forming the hard mask HM and the second material denoted by reference numerals 15, 17, and 19 are Si, SiO, SiN, and Ta. Materials by which the etching rate of the second material is higher than that of the first material are combined from these materials, and the etching conditions of RIE are adjusted. Note that the same material can also be selected as the first and second materials. In this case, the etching rate is adjusted by the RIE conditions.

### [4] Principles of Multilevel Memories

### [4-1] Quaternary Memory

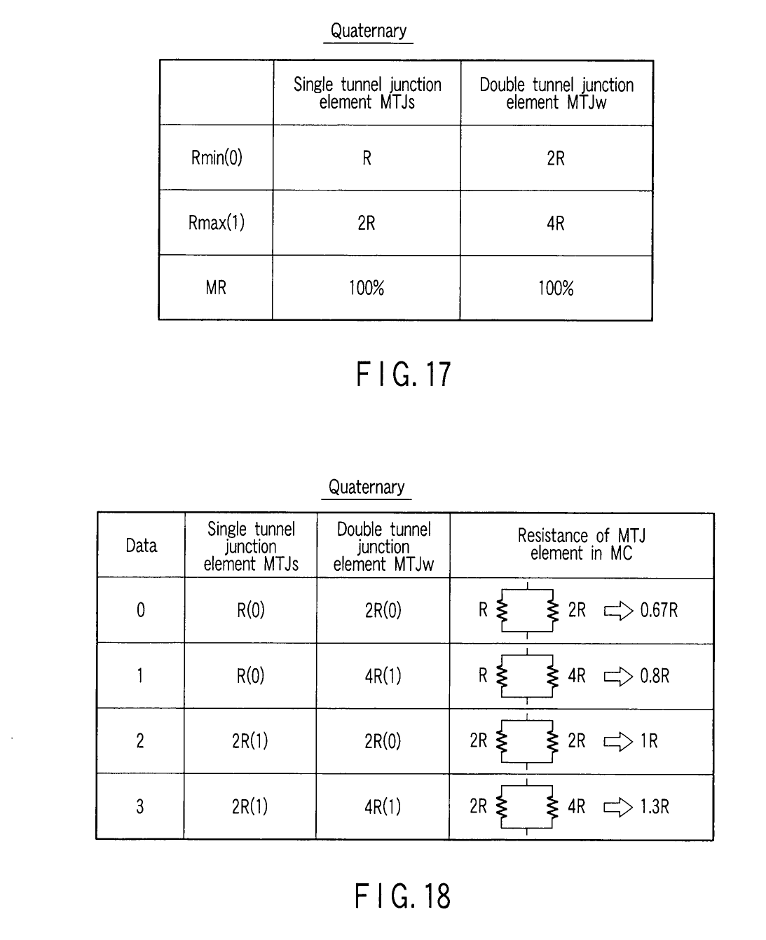

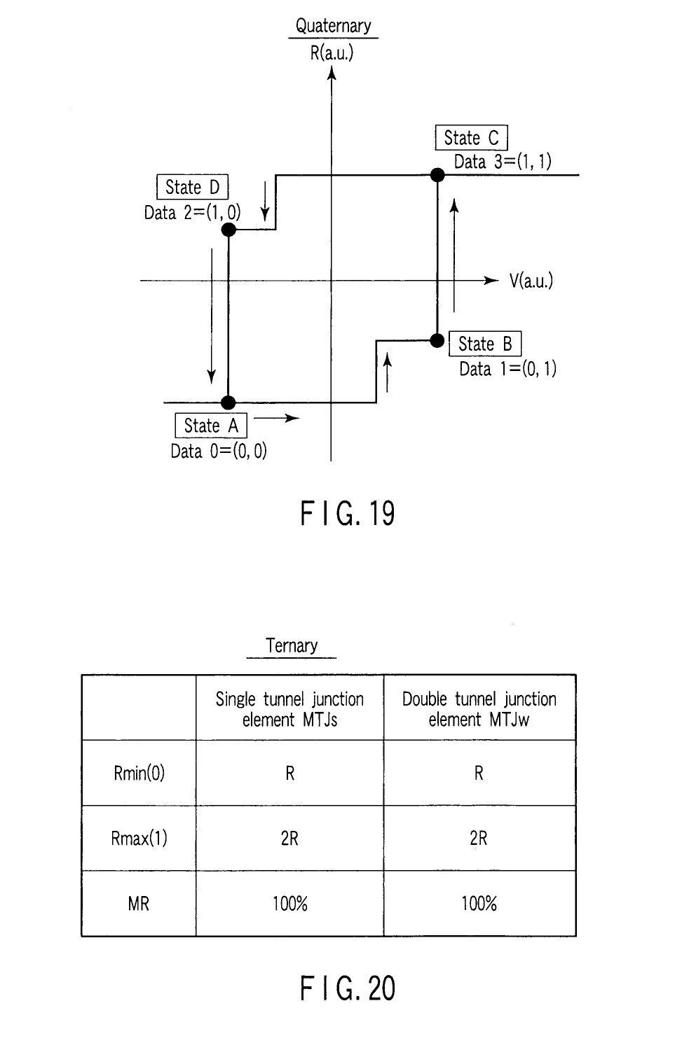

FIG. 17 is a view for explaining the resistance values in a low-resistance state and high-resistance state of a single tunnel junction element and double tunnel junction element of a quaternary memory according to the embodiment of the present invention. FIG. 18 is a view for explaining quaternary data of a memory cell according to the embodiment of the present invention. FIG. 19 is a graph showing changes in resistance, when a voltage is applied, of the quaternary memory according to the embodiment of the present invention. The principle of the quaternary memory will be explained below.

As shown in FIG. 17, in the single tunnel junction element MTJs according to this embodiment, a resistance value Rmin in the low-resistance state (state 0) is defined as “R”, and a resistance value Rmax in the high-resistance state (state 1) is defined as “2R”. Accordingly, the MR (Magneto-Resistance) ratio of the single tunnel junction element MTJs is 100%.

On the other hand, in the double tunnel junction element MTJw according to this embodiment, the resistance value Rmin in the low-resistance state is defined as “2R”, and the resistance value Rmax in the high-resistance state is defined as “4R”. Accordingly, the MR ratio of the double tunnel junction element MTJw is 100%.

In this case, the overall resistance of the memory cell MC including the single tunnel junction element MTJs and double tunnel junction element MTJw connected in parallel takes four values. In this embodiment, these four values are defined as data 0 to 3 as shown in FIG. 18.

Data 0 is the case where both the single tunnel junction element MTJs and double tunnel junction element MTJw are in the low-resistance state (state 0). In this case, an overall resistance Ω of the memory cell MC is the resistance when R and 2R are connected in parallel, i.e., 0.67R.

Data 1 is the case where the single tunnel junction element MTJs is in the low-resistance state (state 0), and the double tunnel junction element MTJw is in the high-resistance state (state 1). In this case, the overall resistance Ω of the memory cell MC is the resistance when R and 4R are connected in parallel, i.e., 0.8R.

Data 2 is the case where the single tunnel junction element MTJs is in the high-resistance state (state 1), and the double tunnel junction element MTJw is in the low-resistance state (state 0). In this case, the overall resistance Ω of the memory cell MC is the resistance when 2R and 2R are connected in parallel, i.e., 1R.

Data 3 is the case where both the single tunnel junction element MTJs and double tunnel junction element MTJw are in the high-resistance state (state 1). In this case, the overall resistance of the memory cell MC is the resistance when 2R and 4R are connected in parallel, i.e., 1.3R.

Changes in resistance of the memory cell MC when a voltage is applied will be explained below with reference to FIG. 19.

In state A, both the single tunnel junction element MTJs and double tunnel junction element MTJw are in the low-resistance state. State A like this is defined as “data 0”.

When the voltage application amount is increased from state A, the magnetization in the recording layer Fw that undergoes the spin torque from the upper fixed layer Pw2 and lower fixed layer Pw1 reverses to set the double tunnel junction element MTJw in the high-resistance state. This is state B. That is, in state B, the single tunnel junction element MTJs remains in the low-resistance state, and the double tunnel junction element MTJw is in the high-resistance state. This state is defined as “data 1”.

When the voltage application amount is further increased from state B, the magnetization in the recording layer Fs reverses to set the single tunnel junction element MTJs in the high-resistance state. This is state C. That is, in state C, both the single tunnel junction element MTJs and double tunnel junction element MTJw are in the high-resistance state. State C like this is defined as “data 3”.

When the voltage application amount is reduced from state C, the magnetization in the recording layer Fw that undergoes the spin torque from the upper fixed layer Pw2 and lower fixed layer Pw1 reverses to set the double tunnel junction element MTJw in the low-resistance state. This is state D. That is, in state D, the single tunnel junction element MTJs remains in the high-resistance state, and the double tunnel junction element MTJw is in the low-resistance state. This state is defined as “data 2”.

When the voltage application amount is further reduced from state D, the magnetization in the recording layer Fs reverses to set the single tunnel junction element MTJs in the low-resistance state, so the memory cell returns to state A.

The above loop makes it possible to achieve the quaternary resistance states by one selection transistor Tr, and form a 2-bit (quaternary) spin injection type MRAM by a cell area of 6F².

### [4-2] Ternary Memory

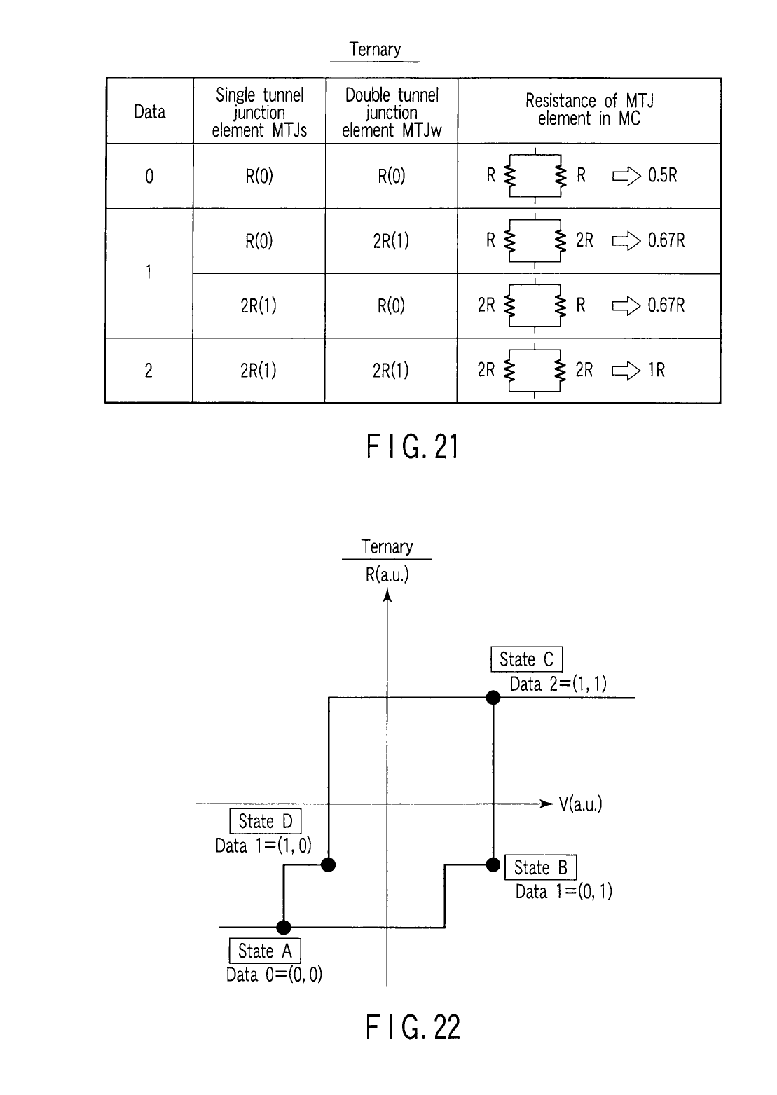

FIG. 20 is a view for explaining the resistance values in the low-resistance state and high-resistance state of a single tunnel junction element and double tunnel junction element of a ternary memory according to the embodiment of the present invention. FIG. 21 is a view for explaining ternary data of a memory cell according to the embodiment of the present invention. FIG. 22 is a graph showing changes in resistance, when a voltage is applied, of the ternary memory according to the embodiment of the present invention. The principle of the ternary memory will be explained below.

As shown in FIG. 20, in the single tunnel junction element MTJs according to this embodiment, the resistance value Rmin in the low-resistance state (state 0) is defined as “R”, and the resistance value Rmax in the high-resistance state (state 1) is defined as “2R”. Accordingly, the MR (Magneto-Resistance) ratio of the single tunnel junction element MTJs is 100%.

Likewise, in the double tunnel junction element MTJw according to this embodiment, the resistance value Rmin in the low-resistance state is defined as “R”, and the resistance value Rmax in the high-resistance state is defined as “2R”. Accordingly, the MR ratio of the double tunnel junction element MTJw is 100%.

As described above, the resistance values Rmin in the low-resistance state of the single tunnel junction element MTJs and double tunnel junction element MTJw are defined to have the same value, and the resistance value Rmax in the high-resistance state of the single tunnel junction element MTJs and double tunnel junction element MTJw are defined to have the same value.

In this case, the overall resistance of the memory cell MC including the single tunnel junction element MTJs and double tunnel junction element MTJw connected in parallel takes three values. In this embodiment, these three values are defined as data 0 to 2 as shown in FIG. 21.

Data 0 is the case where both the single tunnel junction element MTJs and double tunnel junction element MTJw are in the low-resistance state (state 0). In this case, the overall resistance Ω of the memory cell MC is the resistance when R and R are connected in parallel, i.e., 0.5R.

Data 1 is the case where the single tunnel junction element MTJs is in the low-resistance state (state 0), and the double tunnel junction element MTJw is in the high-resistance state (state 1), or the case where the single tunnel junction element MTJs is in the high-resistance state (state 1), and the double tunnel junction element MTJw is in the low-resistance state (state 0). In these cases, the overall resistance Ω of the memory cell MC is the resistance when R and 2R are connected in parallel, i.e., 0.67R.

Data 2 is the case where both the single tunnel junction element MTJs and double tunnel junction element MTJw are in the high-resistance state (state 1). In this case, the overall resistance Ω of the memory cell MC is the resistance when 2R and 2R are connected in parallel, i.e., 1R.

Changes in resistance of the memory cell MC when a voltage is applied will be explained below with reference to FIG. 22.

In state A, both the single tunnel junction element MTJs and double tunnel junction element MTJw are in the low-resistance state. State A like this is defined as “data 0”.

When the voltage application amount is increased from state A, the magnetization in the recording layer Fw that undergoes the spin torque from the upper fixed layer Pw2 and lower fixed layer Pw1 reverses to set the double tunnel junction element MTJw in the high-resistance state. This is state B. That is, in state B, the single tunnel junction element MTJs remains in the low-resistance state, and the double tunnel junction element MTJw is in the high-resistance state. This state is defined as “data 1”.

When the voltage application amount is further increased from state B, the magnetization in the recording layer Fs reverses to set the single tunnel junction element MTJs in the high-resistance state. This is state C. That is, in state C, both the single tunnel junction element MTJs and double tunnel junction element MTJw are in the high-resistance state. State C like this is defined as “data 2”.

When the voltage application amount is reduced from state C, the magnetization in the recording layer Fw that undergoes the spin torque from the upper fixed layer Pw2 and lower fixed layer Pw1 reverses to set the double tunnel junction element MTJw in the low-resistance state. This is state D. That is, in state D, the single tunnel junction element MTJs remains in the high-resistance state, and the double tunnel junction element MTJw is in the low-resistance state. The resistance value in this state is the same as that in state B, so the state is defined as “data 1”.

When the voltage application amount is further reduced from state D, the magnetization in the recording layer Fs reverses to set the single tunnel junction element MTJs in the low-resistance state, so the memory cell returns to state A.

The above loop makes it possible to achieve the ternary resistance states by one selection transistor Tr, and form a ternary spin injection type MRAM by a cell area of 6F².

### [5] Write Operation

This embodiment adopts a spin injection write method. In this spin injection write, the magnetization directions in the fixed layer and recording layer become parallel or antiparallel in accordance with the direction of an electric current flowing between the fixed layer and recording layer. Therefore, the direction of an electric current is defined as follows.

When recording state 1, an electric current is supplied from the fixed layer to the recording layer. That is, electrons are injected into the fixed layer from the recording layer. This makes the magnetization directions in the fixed layer and recording layer opposite, i.e., antiparallel. This high-resistance state is defined as state 1.

When recording state 0, an electric current is supplied from the recording layer to the fixed layer of the MTJ element MTJ. That is, electrons are injected into the recording layer from the fixed layer. This makes the magnetization directions in the fixed layer and recording layer the same, i.e., parallel. This low-resistance state is defined as state 0.

Note that in the double tunnel junction element MTJw shown in FIG. 2, state 0 or 1 is defined when the magnetization directions in the fixed layer Pw1 and recording layer Fw change to the parallel or antiparallel state.

### [6] Read Operation

A read operation of this embodiment uses the magnetoresistive effect.

A bit line BL and read word line corresponding to a selected cell are selected, and the selection transistor Tr for read is turned on. A read current is supplied to the single tunnel junction element MTJs and double tunnel junction element MTJw by applying a voltage to the bit line BL and a source line. On the basis of this read current, the overall resistance value of the cell including the single tunnel junction element MTJs and double tunnel junction element MTJw is read out. Whether the recording state is “0” or “1” is determined by an amplifying operation performed via a sense amplifier.

Note that the read operation can be performed by applying a constant voltage and reading out a current value, or supplying a constant current and reading out a voltage value.

### [7] MTJ Element

### [7-1] Magnetization Arrangement

The magnetization directions in the fixed layer and recording layer of each of the single tunnel junction element MTJs and double tunnel junction element MTJw can be perpendicular to the film surfaces (a perpendicular magnetization type element), or parallel to the film surfaces (a parallel magnetization type element or longitudinal magnetization type element).

Note that the perpendicular magnetization type MTJ element has the advantage that the longitudinal direction of the element shape does not determine the magnetization direction unlike in the conventional element.

### [7-2] Materials

Examples of the materials of the single tunnel junction element MTJs and double tunnel junction element MTJw are as follows.

As the material of the fixed layer and recording layer, it is favorable to use any of Fe, Co, Ni, alloys of these metals, magnetite having a high spin polarization ratio, oxides such as CrO₂ and RXMnO_{3-y} (R; a rare earth element, and X; Ca, Ba, or Sr), and Heusler alloys such as NiMnSb and PtMnSb. These magnetic materials may also contain more or less nonmagnetic elements such as Ag, Cu, Au, Al, Mg, Si, Bi, Ta, B, C, O, N, Pd, Pt, Zr, Ir, W, Mo, Nb, and Ru, provided that the materials do not lose their ferromagnetism.

The fixed layer is preferably made of an alloy containing one of Co, Fe, Ni, Ir, Pt, Mn, B, and Ru. The recording layer is preferably made of an alloy containing one of Co, Fe, Ni, and B. In these cases, each of the fixed layer and recording layer can be a single-layered film made of the alloy, or a stacked film including a plurality of films.

The nonmagnetic layer is made of a paramagnetic metal or insulating oxide. Examples of the paramagnetic metal are Cu, Au, and Ag. Examples of the insulating oxide are Al₂O₃ and MgO. It is also possible to use various dielectric materials such as SiO₂, AlN, Bi₂O₃, MgF₂, CaF₂, SrTiO₂, and AlLaO₃. Oxygen, nitrogen, and fluorine deficiencies may exist in these dielectric materials.

An antiferromagnetic layer for fixing the magnetization direction in the fixed layer may also be formed on the surface of the fixed layer away from the surface opposing the tunnel junction layer. As the material of this antiferromagnetic layer, it is favorable to use, e.g., Fe—Mn, Pt—Mn, Pt—Cr—Mn, Ni—Mn, Ir—Mn, NiO, or Fe₂O₃.

### [7-3] Fixed Layer and Recording Layer

Each of the fixed layer and recording layer is not limited to a single layer as shown in the drawing. For example, each of the fixed layer and recording layer may also be a stacked film including a plurality of ferromagnetic layers. At least one of the fixed layer and recording layer may also have an antiferromagnetic coupling structure which includes three layers, i.e., a first ferromagnetic layer/nonmagnetic layer/second ferromagnetic layer, and in which the first and second ferromagnetic layers magnetically couple with each other (by interlayer exchange coupling) so that the magnetization directions in these layers are antiparallel, or a ferromagnetic coupling structure in which the first and second ferromagnetic layers magnetically couple with each other (by interlayer exchange coupling) so that the magnetization directions in these layers are parallel.

### [7-4] Tunnel Junction Layers

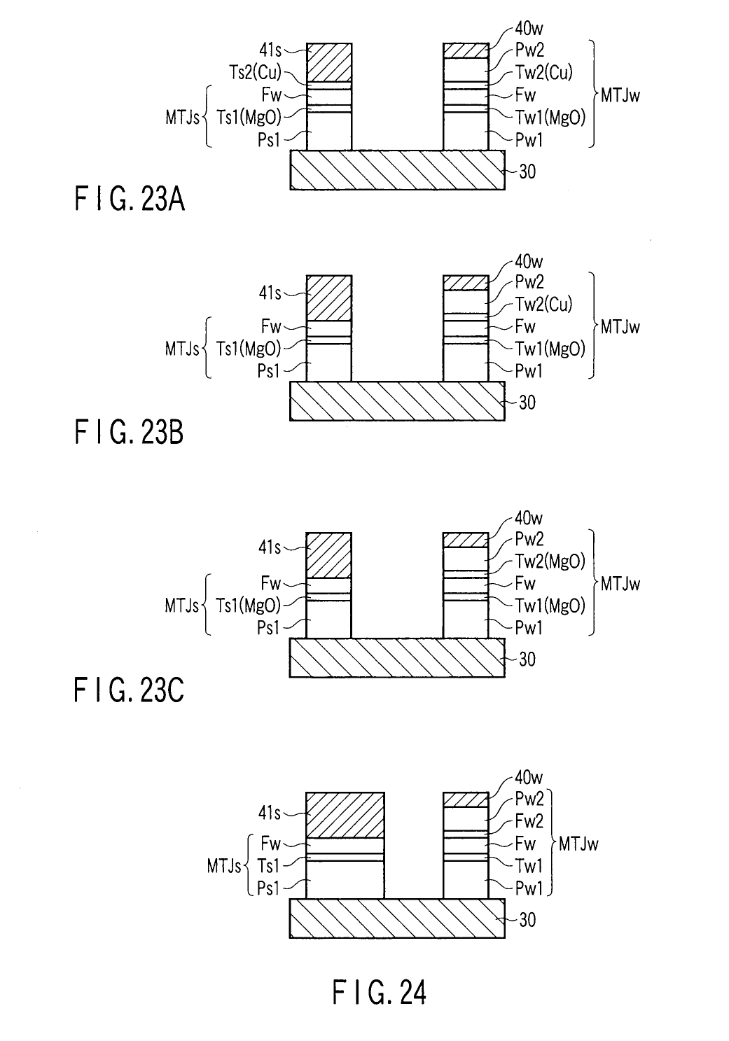

FIGS. 23A to 23C illustrate examples of the tunnel junction layers of the single tunnel junction element and double tunnel junction element according to the embodiment of the present invention.

As shown in FIG. 23A, the lower tunnel junction layers Ts1 and Tw1 and the upper tunnel junction layers Ts2 and Tw2 may also be made of different materials. For example, an insulating oxide such as MgO is used as the lower tunnel junction layers Ts1 and Tw1, and a paramagnetic metal such as Cu is used as the upper tunnel junction layers Ts2 and Tw2.

As shown in FIG. 23B, the tunnel junction layer Ts2 above in the upper portion of the single tunnel junction element MTJs may also be removed. That is, the upper electrode 41s is in direct contact with the surface of the recording layer Fw away from the surface opposing the tunnel junction layer Ts1, and the upper electrode 40w is in direct contact with the surface of the fixed layer Pw2 away from the surface opposing the tunnel junction layer Tw2. In this case, the tunnel junction layer Ts1 is made of, e.g., MgO because it is desirably made of an insulating oxide, and the tunnel junction layer Tw1 on the same layer level as that of the tunnel junction layer Ts1 is also made of MgO. This is so because the process is facilitated when the tunnel junction layers Ts1 and Tw1 are formed by using the same material at the same time.

As shown in FIG. 23C, the lower tunnel junction layers Ts1 and Tw1 and the upper tunnel junction layers Ts2 and Tw2 may also be made of the same material. For example, MgO is used as the tunnel junction layers Ts1, Tw1, Ts2, and Tw2. When using a material such as MgO having a high resistance value, the upper tunnel junction layer Ts2 of the single tunnel junction element MTJs is desirably removed.

Note that in the double tunnel junction element MTJw shown in FIG. 23C, the film thickness of the upper tunnel junction layer Tw2 is preferably made smaller than that of the lower tunnel junction layer Tw1.

### [7-5] Area

FIG. 24 shows an example in which the sizes of the single tunnel junction element and double tunnel junction element according to the embodiment of the present invention are different.

As shown in FIG. 24, the area of the planar shape of the single tunnel junction element MTJs may also be made larger than that of the planar shape of the double tunnel junction element MTJw. Consequently, the resistance value of the single tunnel junction element MTJs can be made lower than that of the double tunnel junction element MTJw. This makes it possible to implement a multilevel memory by producing a resistance difference between the single tunnel junction element MTJs and double tunnel junction element MTJw.

### [8] Effects

In the embodiment of the present invention, a cell is formed by connecting the single tunnel junction element MTJs and double tunnel junction element MTJw in parallel, and the selection transistor Tr is connected to the cell. In the single tunnel junction element MTJs and double tunnel junction element MTJw in one cell, all threshold current values that cause magnetization reversal by the spin torque are different in states 1 and 0. This makes it possible to implement a quaternary memory and the like. Accordingly, a large-capacity, multi-bit, spin injection type magnetoresistive random access memory can be implemented.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic random access memory comprising:
a single tunnel junction element which includes a first fixed layer having a fixed magnetization direction, a first recording layer having a reversible magnetization direction, and a first nonmagnetic layer formed between the first fixed layer and the first recording layer, and in which the magnetization directions in the first fixed layer and the first recording layer take one of a parallel state and an antiparallel state in accordance with a direction of an electric current flowing between the first fixed layer and the first recording layer;
a double tunnel junction element which includes a second fixed layer and a third fixed layer each having a fixed magnetization direction, a second recording layer having a reversible magnetization direction, a second nonmagnetic layer formed between the second fixed layer and the second recording layer, and a third nonmagnetic layer formed between the third fixed layer and the second recording layer, and in which the magnetization directions in the second fixed layer and the second recording layer take one of the parallel state and the antiparallel state in accordance with a direction of an electric current flowing between the second fixed layer and the second recording layer; and
a transistor connected to a memory cell having the single tunnel junction element and the double tunnel junction element connected in parallel.

2. The memory according to claim 1, further comprising:
a lower electrode on which the single tunnel junction element and the double tunnel junction element are formed;
a first upper electrode formed on the single tunnel junction element;
a second upper electrode formed on the double tunnel junction element; and
a bit line formed on the first upper electrode and the second upper electrode.

3. The memory according to claim 2, wherein
heights of upper surfaces of the first fixed layer and the second fixed layer are equal,
heights of upper surfaces of the first nonmagnetic layer and the second nonmagnetic layer are equal,
heights of upper surfaces of the first recording layer and the second recording layer are equal, and
heights of upper surfaces of the first upper electrode and the second upper electrode are equal.

4. The memory according to claim 1, wherein the first nonmagnetic layer and the second nonmagnetic layer are made of an insulating oxide, and the third nonmagnetic layer is made of a paramagnetic metal.

5. The memory according to claim 1, further comprising a fourth nonmagnetic layer formed on a surface of the first recording layer away from a surface opposing the first nonmagnetic layer.

6. The memory according to claim 1, which further comprises:
a first upper electrode formed in direct contact with a surface of the first recording layer away from a surface opposing the first nonmagnetic layer; and
a second upper electrode formed in direct contact with a surface of the third fixed layer away from a surface opposing the third nonmagnetic layer, and
in which the first nonmagnetic layer and the second nonmagnetic layer are made of an insulating oxide, and the third nonmagnetic layer is made of a paramagnetic metal.

7. The memory according to claim 1, which further comprises:
a first upper electrode formed in direct contact with a surface of the first recording layer away from a surface opposing the first nonmagnetic layer; and
a second upper electrode formed in direct contact with a surface of the third fixed layer away from a surface opposing the third nonmagnetic layer, and
in which the first nonmagnetic layer, the second nonmagnetic layer, and the third nonmagnetic layer are made of an insulating oxide.

8. The memory according to claim 1, wherein
side surfaces of the first fixed layer, the first nonmagnetic layer, and the first recording layer are aligned, and
side surfaces of the second fixed layer, the third fixed layer, the second nonmagnetic layer, the third nonmagnetic layer, and the second recording layer are aligned.

9. The memory according to claim 1, which further comprises a bit line connected to the single tunnel junction element and the double tunnel junction element, and
in which the single tunnel junction element and the double tunnel junction element are arranged straight in a direction in which the bit line runs.

10. The memory according to claim 1, wherein an area of a planar shape of the single tunnel junction element is larger than that of a planar shape of the double tunnel junction element.

11. The memory according to claim 1, wherein the magnetization directions in the first fixed layer, the second fixed layer, the third fixed layer, the first recording layer, and the second recording layer are perpendicular to a film surface.

12. A magnetic random access memory manufacturing method comprising:
forming a transistor;
forming a lower electrode connecting to the transistor;
forming, on the lower electrode, a first stacked portion in which a first fixed layer, a first nonmagnetic layer, a first recording layer, a second nonmagnetic layer, a second fixed layer, and a first upper electrode are sequentially stacked, and a second stacked portion in which a third fixed layer, a third nonmagnetic layer, a second recording layer, a fourth nonmagnetic layer, a fourth fixed layer, and a second upper electrode are sequentially stacked;
forming an interlayer dielectric film covering the first stacked portion and the second stacked portion;
exposing only the first upper electrode by partially removing the interlayer dielectric film;
forming a trench by removing the first upper electrode and the second fixed layer;
forming a third upper electrode in the trench; and
forming a bit line on the first upper electrode and the third upper electrode,
wherein the first fixed layer, the first nonmagnetic layer, and the first recording layer form a single tunnel junction element,
the third fixed layer, the third nonmagnetic layer, the second recording layer, the fourth nonmagnetic layer, and the fourth fixed layer form a double tunnel junction element, and
the transistor is connected to a memory cell having the single tunnel junction element and the second single tunnel junction element connected in parallel by the lower electrode and the bit line.

13. The method according to claim 12, further comprising:
forming a stacked magnetic film on the lower electrode after forming the lower electrode;
forming a first insulating film made of a first material on the stacked magnetic film;
forming a second insulating film made of a second material on the first insulating film;
forming a third insulating film made of the first material on only a side surface of the second insulating film;
depositing a fourth insulating film made of a second material around the third insulating film and on the second insulating film;
exposing the second insulating film and the third insulating film by planarizing the fourth insulating film;
removing the first insulating film, the second insulating film, and the fourth insulating film from a region not covered with the third insulating film, thereby forming a mask including the first insulating film and the third insulating film on the stacked magnetic film; and
forming the first stacked portion and the second stacked portion on the lower electrode by removing the stacked magnetic film by using the mask.

14. The method according to claim 13, further comprising:
forming the second insulating film into a line running in a first direction after forming the second insulating film on the first insulating film;
forming a fifth insulating film made of the first material on the second insulating film, the third insulating film, and the fourth insulating film, after exposing the second insulating film;
depositing a sixth insulating film made of the second material on the fifth insulating film, and forming the sixth insulating film into a line running in a second direction perpendicular to the first direction;
forming a seventh insulating film made of the first material on only a side surface of the sixth insulating film; and
removing the first insulating film, the second insulating film, the third insulating film, the fourth insulating film, the fifth insulating film, the sixth insulating film, and the seventh insulating film from a region except for a region where the third insulating film and the seventh insulating film intersect each other, thereby forming the mask including the first insulating film, the third insulating film, the fifth insulating film, and the seventh insulating film on the stacked magnetic film.

15. The method according to claim 13, wherein the first material is a silicon nitride film, and the second material is a silicon oxide film.

16. The method according to claim 12, wherein the first nonmagnetic layer and the third nonmagnetic layer are made of an insulating oxide, and the fourth nonmagnetic layer is made of a paramagnetic metal.

17. The method according to claim 12, wherein when forming the trench, only the first upper electrode and the second fixed layer are removed, and the second nonmagnetic layer is left behind.

18. The method according to claim 12, wherein
when forming the trench, the second nonmagnetic layer is removed together with the first upper electrode and the second fixed layer, and
the first nonmagnetic layer and the third nonmagnetic layer are made of an insulating oxide, and the fourth nonmagnetic layer is made of a paramagnetic metal.

19. The method according to claim 12, wherein
when forming the trench, the second nonmagnetic layer is removed together with the first upper electrode and the second fixed layer, and
the first nonmagnetic layer, the third nonmagnetic layer, and the fourth nonmagnetic layer are made of an insulating oxide.

20. The method according to claim 12, wherein the single tunnel junction element and the double tunnel junction element are arranged straight in a direction in which the bit line runs.
